(19) United States
(12) Patent Application Publication
(10) Pub. No.: US 2026/0082512 A1
(43) Pub. Date: Mar. 19, 2026

(54) LIQUID IMMERSION COOLING DEVICE

(71) Applicant: MITSUBISHI HEAVY INDUSTRIES, LTD., Tokyo (JP)

(72) Inventors: Hidetaka Kafuku, Tokyo (JP); Nobuhide Hara, Tokyo (JP); Shuji Fujii, Tokyo (JP); Naoki Ogawa, Tokyo (JP); Taisuke Tsukamoto, Tokyo (JP); Kohei Kanamori, Tokyo (JP); Shinichi Okamoto, Tokyo (JP)

(73) Assignee: MITSUBISHI HEAVY INDUSTRIES, LTD., Tokyo (JP)

(21) Appl. No.: 19/106,373

(22) PCT Filed: Feb. 17, 2023
(86) PCT No.: PCT/JP2023/005782

§ 371 Date: Feb. 25, 2025

(30) Foreign Application Priority Data
Aug. 26, 2022 (JP) 2022-134839

(51) Int. Cl. H05K 7/20; G06F 1/20

(52) U.S. Cl. CPC H05K 7/203; G06F 1/20; H05K 7/20327; H05K 7/20818; G06F 2200/201

(57) ABSTRACT

A liquid immersion cooling device cools a heating element provided on a board, and includes: a casing configured to accommodate the board inside and store a refrigerant in an inner lower portion; a cover configured to surround at least the heating element and having an opening portion at least in a part of the cover; a condensation portion provided above a liquid level of the refrigerant in the casing and configured to condense the refrigerant that is evaporated; a refrigerant receiving portion provided above the liquid level and below the condensation portion and configured to receive the refrigerant in a liquid phase condensed by the condensation portion; and a refrigerant introduction flow channel configured to guide the refrigerant received by the refrigerant receiving portion into the cover.

### TECHNICAL FIELD

The present disclosure relates to a liquid immersion cooling device.

Priority is claimed on Japanese Patent Application No. 2022-134839, filed Aug. 26, 2022, the content of which is incorporated herein by reference.

### BACKGROUND ART

Patent Document 1 discloses a method of recovering a refrigerant used for liquid immersion cooling. In this method of recovering the refrigerant, the refrigerant is distilled in a distillation tank to separate a low volatile contaminant. The evaporated refrigerant is recovered in a circulation tank.

### CITATION LIST

### Patent Document

Patent Document 1: U.S. Pat. No. 10,773,192

### SUMMARY OF INVENTION

### Technical Problem

However, the method of recovering the refrigerant described in Patent Document 1 requires a large-scale device such as the distillation tank. Therefore, there is a problem in that the entire device becomes large. Further, a heater is used for distillation of the refrigerant. Therefore, there is also a problem in that the power consumption is increased.

The present disclosure has been made in order to solve the above-described problems, and an object of the present disclosure is to provide a liquid immersion cooling device that can reduce power consumption while achieving size reduction.

### Solution to Problem

In order to achieve the above-described object, the present disclosure provides a liquid immersion cooling device that cools a heating element provided on a board, the liquid immersion cooling device including: a casing configured to accommodate the board inside and store a refrigerant in an inner lower portion; a cover configured to surround at least the heating element and having an opening portion at least in a part of the cover; a condensation portion provided above a liquid level of the refrigerant in the casing and configured to condense the refrigerant that is evaporated; a refrigerant receiving portion provided above the liquid level and below the condensation portion and configured to receive the refrigerant in a liquid phase condensed by the condensation portion; and a refrigerant introduction flow channel configured to guide the refrigerant received by the refrigerant receiving portion into the cover.

### Advantageous Effects of Invention

With the liquid immersion cooling device according to the present disclosure, it is possible to reduce the power consumption while achieving the size reduction.

### BRIEF DESCRIPTION OF DRAWINGS

FIG. 1 A schematic view showing the configuration of a liquid immersion cooling device according to a first embodiment of the present disclosure.

FIG. 2 A schematic view showing the configuration of a liquid immersion cooling device according to a second embodiment of the present disclosure.

FIG. 3 A schematic view showing the configuration of a lid portion according to the second embodiment of the present disclosure.

FIG. 4 A schematic view showing the configuration of a liquid immersion cooling device according to a third embodiment of the present disclosure.

FIG. 5 A schematic view showing the configuration of a liquid immersion cooling device according to a fourth embodiment of the present disclosure.

FIG. 6 A schematic view showing the configuration of a liquid immersion cooling device according to a fifth embodiment of the present disclosure.

### DESCRIPTION OF EMBODIMENTS

### First Embodiment

### (Liquid Immersion Cooling Device)

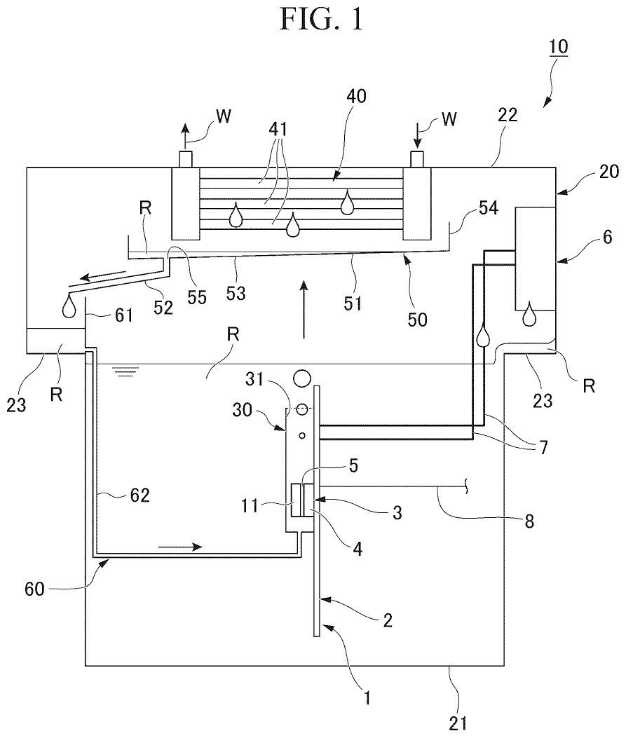

Hereinafter, a liquid immersion cooling device 10 according to a first embodiment of the present disclosure will be described with reference to FIG. 1.

As shown in FIG. 1, the liquid immersion cooling device 10 is used for cooling an electronic device. In the present embodiment, the liquid immersion cooling device 10 is used in a server 1 that performs high-speed calculation.

The server 1 includes a printed circuit board and an electronic component such as a chip of a CPU or a GPU provided on the printed circuit board. Since the CPU or the GPU is a component that is responsible for the high-speed calculation processing, a high load is applied. Therefore, the CPU or the GPU generates heat at a higher temperature than in other portions of the server 1,

Hereinafter, the printed circuit board of the server 1 may be simply referred to as a “board 2”, and the chip such as the CPU or the GPU may be referred to as a “heating element 3”.

The board 2 is formed in a rectangular plate shape. The board 2 is disposed in a vertical posture to extend in an up-down direction.

The heating element 3 is installed to be attached to a surface of the board 2. Therefore, in the present embodiment, the heating element 3 is vertically disposed to extend in the up-down direction, similarly to the board 2. The heating element 3 includes a heating element body 4 and a cooling plate 5 that is made of metal and that is closely attached to the heating element body 4. The cooling plate 5 is provided to radiate heat of the heating element body 4.

The heating element 3 includes, in addition to the CPU and the GPU, all the heating elements that generate heat on the board 2. In addition, the cooling plate 5 need not be provided in the heating element 3.

Power is supplied from a power supply 6 outside the server 1 to the heating element 3. The power supply 6 is connected to the board 2 via a power supply cable 7. The heating element 3 is electrically connected to the power supply 6 via the power supply cable 7 and the board 2. In addition, the board 2 is connected to an external device (not shown) via a communication cable 8. The communication cable 8 is, for example, a LAN cable. The server 1 communicates with the external device through the communication cable 8.

### (Configuration of Liquid Immersion Cooling Device)

Subsequently, a configuration of the liquid immersion cooling device 10 will be described.

The liquid immersion cooling device 10 is a device that cools the heating element 3 by causing a refrigerant R in a liquid phase and the heating element 3 to perform the heat exchange with each other in a state in which the heating element 3 is immersed in the refrigerant R in the liquid phase. The refrigerant R used in the liquid immersion cooling device 10 is an insulating fluid.

As shown in FIG. 1, the liquid immersion cooling device 10 includes a casing 20, a cover 30, a heat sink 11, a condensation portion 40, a refrigerant receiving portion 50, and a refrigerant introduction flow channel 60. FIG. 1 shows a state in which the server 1 is operated and the heating element 3 generates heat.

### (Casing)

The casing 20 accommodates the board 2 inside. The refrigerant R in the liquid phase is stored in an inner lower portion of the casing 20. In the present embodiment, the entire board 2 is immersed in the refrigerant R in the liquid phase stored in the casing 20. In the present embodiment, as an example, a case will be described in which the casing 20 includes a lower portion casing 21, an upper portion casing 22, and a connection wall 23.

The lower portion casing 21 is a bottomed container that is open upward. The lower portion casing 21 is a portion of the casing 20 in which the refrigerant R in the liquid phase is stored. The upper portion casing 22 is provided above the lower portion casing 21. The upper portion casing 22 is a bottomed container that is open downward. In the present embodiment, the opening area of the upper portion casing 22 is larger than the opening area of the lower portion casing 21. The connection wall 23 is formed to protrude outward in a horizontal direction from an opening of the lower portion casing 21. The connection wall 23 connects the opening of the lower portion casing 21 and an opening of the upper portion casing 22.

A closed space is formed by the lower portion casing 21, the upper portion casing 22, and the connection wall 23. In the space in the casing 20, in addition to the board 2, the power supply 6, the power supply cable 7, and the communication cable 8 are accommodated. The board 2 is disposed in the lower portion casing 21. The board 2 is installed at a position floating upward from a bottom portion of the lower portion casing 21. The power supply 6 is installed on the connection wall 23.

In the casing 20, in addition to the refrigerant R in the liquid phase stored in the lower portion casing 21, the refrigerant R in a gas phase is present. The refrigerant R in the gas phase is condensed on the power supply 6 or the power supply cable 7 and then changed to the liquid phase. In addition, since a plasticizer is included in the coating or the like of a cable inside the power supply 6, the power supply cable 7, and the communication cable 8, the plasticizer may be dissolved in the refrigerant R. The refrigerant R in which the plasticizer is dissolved is mixed into the refrigerant R stored in the casing 20 from the cable inside the power supply 6, the power supply cable 7, and the communication cable 8.

### (Cover)

The cover 30 is accommodated inside the casing 20. The cover 30 is attached to the surface of the board 2. The cover 30 is a member that surrounds at least the heating element 3. In the present embodiment, the entire cover 30 is immersed in the refrigerant R stored in the casing 20. The cover 30 has an opening portion 31 in at least a part thereof. The opening portion 31 is provided above the heating element 3. The opening portion 31 is open upward.

### (Heat Sink)

The heat sink 11 is disposed in the cover 30. The heat sink 11 is attached to the cooling plate 5 of the heating element 3. The heat sink 11 is thermally connected to the heating element 3. The heat sink 11 has a structure for increasing a surface area of the heating element 3 and assists cooling of the heating element 3. In the present embodiment, the heat sink 11 is provided separately from the cover 30.

### (Condensation Portion)

The condensation portion 40 is provided above a liquid level of the refrigerant R in the casing 20. The condensation portion 40 condenses the evaporated refrigerant R in the casing 20. The condensation portion 40 is attached to the upper portion casing 22.

The condensation portion 40 according to the present embodiment is a water-cooled condenser. The condensation portion 40 includes a plurality of heat transfer pipes 41, Cooling water W flows through the heat transfer pipe 41. The refrigerant receiving portion 50 is provided below the condensation portion 40.

### (Refrigerant Receiving Portion)

The refrigerant receiving portion 50 is located above the liquid level of the refrigerant R stored in the casing 20. The refrigerant receiving portion 50 receives the refrigerant R in the liquid phase condensed by the condensation portion 40. The refrigerant receiving portion 50 has a receiving portion body 51 and a discharge pipe 52.

The receiving portion body 51 is a container that is open upward. The receiving portion body 51 has a bottom wall 53 and side walls 54. The bottom wall 53 extends in the horizontal direction. An outer peripheral edge of the bottom wall 53 is located outside the condensation portion 40 when viewed in the up-down direction. The bottom wall 53 is provided with a discharge hole 55 that penetrates the bottom wall 53. The bottom wall 53 is inclined to be located downward toward the discharge hole 55. The side walls 54 extend upward from the outer peripheral edge of the bottom wall 53.

The discharge pipe 52 is connected to the discharge hole 55 of the receiving portion body 51. The discharge pipe 52 extends downward from the receiving portion body 51. The discharge pipe 52 is provided to approach the connection wall 23 of the casing 20 toward the lower side. The refrigerant introduction flow channel 60 is provided below a lower end of the discharge pipe 52.

### (Refrigerant Introduction Flow Channel)

The refrigerant introduction flow channel 60 is a flow channel that guides the refrigerant R received by the refrigerant receiving portion 50 into the cover 30. The refrigerant introduction flow channel 60 includes a storage tank 61 and a refrigerant supply pipe 62.

### (Storage Tank)

The storage tank 61 is located directly below the lower end of the discharge pipe 52. The storage tank 61 is a container that is open upward. The refrigerant R received by the refrigerant receiving portion 50 is supplied from the discharge pipe 52 to the storage tank 61. The storage tank 61 stores the refrigerant R received by the refrigerant receiving portion 50. In the present embodiment, the storage tank 61 is provided on the connection wall 23 of the casing 20. The storage tank 61 is located above the liquid level of the refrigerant R stored in the casing 20. The refrigerant supply pipe 62 is provided at a lower portion of the storage tank 61.

### (Refrigerant Supply Pipe)

The refrigerant supply pipe 62 connects the storage tank 61 and the cover 30. The refrigerant supply pipe 62 communicates with the storage tank 61 and the cover 30. The refrigerant supply pipe 62 allows the refrigerant R to flow from the storage tank 61 toward the cover 30. In the present embodiment, one end of the refrigerant supply pipe 62 is connected to the lower portion of the storage tank 61. The other end of the refrigerant supply pipe 62 is connected to a lower portion of the cover 30. In addition, the other end of the refrigerant supply pipe 62 is located below the heating element 3. In the present embodiment, the refrigerant supply pipe 62 is immersed in the refrigerant R stored in the casing 20.

### (Circulation of Refrigerant)

Next, the circulation of the refrigerant R in the liquid immersion cooling device 10 will be described.

In a case where the operation of the server 1 is started, a load is applied to the heating element 3, and the heating element 3 generates heat. Then, the heat exchange is performed between the heating element 3 and the refrigerant R in the cover 30. As a result, the heating element 3 is cooled. On the other hand, the refrigerant R in the cover 30 is heated. As a result, an upward flow is generated in the cover 30. The refrigerant R is discharged to the outside of the cover 30 due to the upward flow.

In the present embodiment, the liquid immersion cooling device 10 cools the heating element 3 by a two-phase cooling method. That is, the liquid immersion cooling device 10 cools the heating element 3 by evaporating the refrigerant R around the heating element 3, to take away latent heat of the evaporation of the refrigerant R from the heating element 3. As a result, the refrigerant R is boiled in the cover 30, and a part of the refrigerant R in the cover 30 is evaporated to form the gas phase.

The refrigerant R that is boiled and evaporated in the cover 30 and the refrigerant R that is evaporated from the liquid level of the refrigerant R in the casing 20 are supplied to the condensation portion 40. The evaporated refrigerant R performs the heat exchange with the cooling water W flowing through the condensation portion 40. As a result, the refrigerant R is condensed and is changed from the gas phase to the liquid phase. The refrigerant R condensed in the condensation portion 40 is recovered by the refrigerant receiving portion 50.

Then, the refrigerant R is supplied from the refrigerant receiving portion 50 to the storage tank 61. The refrigerant R is temporarily stored in the storage tank 61.

The refrigerant R is separated from impurities such as a non-volatile oil component by the evaporation. Therefore, the evaporated refrigerant R is a clean refrigerant R having few impurities, as compared with the refrigerant R from which the plasticizer is eluted by being attached to the power supply 6 or the power supply cable 7, or the refrigerant R stored in the casing 20. The storage tank 61 stores the refrigerant R obtained by condensing the evaporated refrigerant R. Therefore, the storage tank 61 stores the clean refrigerant R having few impurities.

The refrigerant R stored in the storage tank 61 is drawn into the cover 30 through the refrigerant supply pipe 62 due to the upward flow generated by the heat generation of the heating element 3. As a result, during the heat generation of the heating element 3, the clean refrigerant R is always supplied into the cover 30. The refrigerant R supplied to the cover 30 is discharged to the outside of the cover 30 again after performing the heat exchange with the heating element 3. In this manner, the refrigerant R circulates in the cooling device.

### (Operations and Effects)

With the liquid immersion cooling device 10 according to the present embodiment, the following operations and effects are exhibited.

In the present embodiment, the liquid immersion cooling device 10 includes the casing 20, the cover 30, the condensation portion 40, the refrigerant receiving portion 50, and the refrigerant introduction flow channel 60. The casing 20 accommodates the board 2 inside. The refrigerant R is stored in the inner lower portion of the casing 20. The cover 30 surrounds at least the heating element 3. The cover 30 bas an opening portion 31 in at least a part thereof. The condensation portion 40 is provided above a liquid level of the refrigerant R in the casing 20. The condensation portion 40 condenses the evaporated refrigerant R. The refrigerant receiving portion 50 is provided above the liquid level of the refrigerant R in the casing 20 and below the condensation portion 40. The refrigerant receiving portion 50 receives the refrigerant R in the liquid phase condensed by the condensation portion 40. The refrigerant introduction flow channel 60 guides the refrigerant R received by the refrigerant receiving portion 50 into the cover 30.

In the present embodiment, the refrigerant R in the gas phase in the casing 20 is condensed by the condensation portion 40 and then changed to the liquid phase. The refrigerant R in the liquid phase is guided into the cover 30 by the refrigerant receiving portion 50 and the refrigerant introduction flow channel 60. The refrigerant R condensed from the gas phase does not contain impurities such as a non-volatile oil component. Therefore, the refrigerant R supplied into the cover 30 is the clean refrigerant R having few impurities.

In addition, the refrigerant R in the cover 30 is heated by the heating element 3. As a result, the upward flow is generated in the cover 30. The upward flow draws the clean refrigerant R in the refrigerant introduction flow channel 60 into the cover 30. As a result, the clean refrigerant R is always supplied to the heating element 3 while the heating element 3 is generating heat.

As described above, according to the present embodiment, it is possible to supply the clean refrigerant R having few impurities to the heating element 3 without providing a large device such as a distillation tank. Therefore, the liquid immersion cooling device 10 can be reduced in size. Further, a heater for distilling the refrigerant R is not necessary. In addition, since the refrigerant R is circulated by the upward flow generated by the heat generation of the heating element 3, a motor for circulating the refrigerant R is not necessary. Therefore, the power consumption of the liquid immersion cooling device 10 can be reduced.

In the present embodiment, the opening portion 31 is provided above the heating element 3.

As a result, the refrigerant R in the cover 30 is likely to flow out of the cover 30 through the opening portion 31 due to the upward flow generated by the heating element 3. Therefore, the clean refrigerant R is smoothly supplied to the heating element 3. Therefore, the precipitation and the accumulation of the impurities such as the oil component in the heating element 3 and the heat sink 11 are suppressed. Therefore, the decrease in the cooling efficiency of the liquid immersion cooling device 10 is suppressed.

In the present embodiment, the storage tank 61 is located above the liquid level of the refrigerant R stored in the casing 20.

As a result, the liquid level of the refrigerant R in the storage tank 61 is higher than the liquid level in the casing 20. Therefore, a pressure for causing the refrigerant R to flow from the storage tank 61 toward the cover 30 is generated in the refrigerant introduction flow channel 60. Therefore, the liquid immersion cooling device 10 can circulate the refrigerant R more smoothly.

In the present embodiment, the liquid immersion cooling device 10 includes the heat sink 11 thermally connected to the heating element 3.

As a result, a contact area between the heating element 3 and the refrigerant R is increased. Therefore, the cooling efficiency of the liquid immersion cooling device 10 can be improved.

In the present embodiment, the other end of the refrigerant supply pipe 62 is connected to the cover 30 below the heating element 3.

As a result, the clean refrigerant R is directly supplied to the cooling plate 5 of the heating element 3. Therefore, the precipitation and the accumulation of the impurities such as the oil component in the heating element 3 and the heat sink 11 are suppressed. Therefore, the decrease in the cooling efficiency of the liquid immersion cooling device 10 is suppressed. In addition, even in a case where the oil component is attached to the heating element 3 and the heat sink 11, the liquid immersion cooling device 10 can dissolve the attached oil component in the clean refrigerant R to remove the oil component.

In the first embodiment, the storage tank 61 is located above the liquid level of the refrigerant R stored in the casing 20, but the present disclosure is not limited to this. For example, the storage tank 61 may be disposed at a lower position than the liquid level of the refrigerant R stored in the casing 20.

In the first embodiment, in the present embodiment, the liquid immersion cooling device 10 cools the heating element 3 by the two-phase cooling method, but the present disclosure is not limited to this. The liquid immersion cooling device 10 may cool the heating element 3 by a single-phase cooling method. In this case, the refrigerant R heated by the heating element 3 in the cover 30 flows out of the cover 30 in a liquid-phase state.

In the first embodiment, the casing 20 includes the lower portion casing 21, the upper portion casing 22, and the connection wall 23, and the opening area of the upper portion casing 22 is larger than the opening area of the lower portion casing 21, but the present disclosure is not limited to this. For example, the opening area of the upper portion casing 22 may be smaller than the opening area of the lower portion casing 21. In addition, for example, the casing 20 may be a cubic container that does not have the connection wall 23. In addition, the storage tank 61 and the discharge pipe 52 may not be provided, the receiving portion body 51 may be able to temporarily store the refrigerant R instead of the storage tank 61, and the refrigerant supply pipe 62 may be connected to the discharge hole 55 of the receiving portion body 51. The refrigerant R is directly supplied from the receiving portion body 51 to the refrigerant supply pipe 62 by connecting the refrigerant supply pipe 62 to the discharge hole 55.

### Second Embodiment

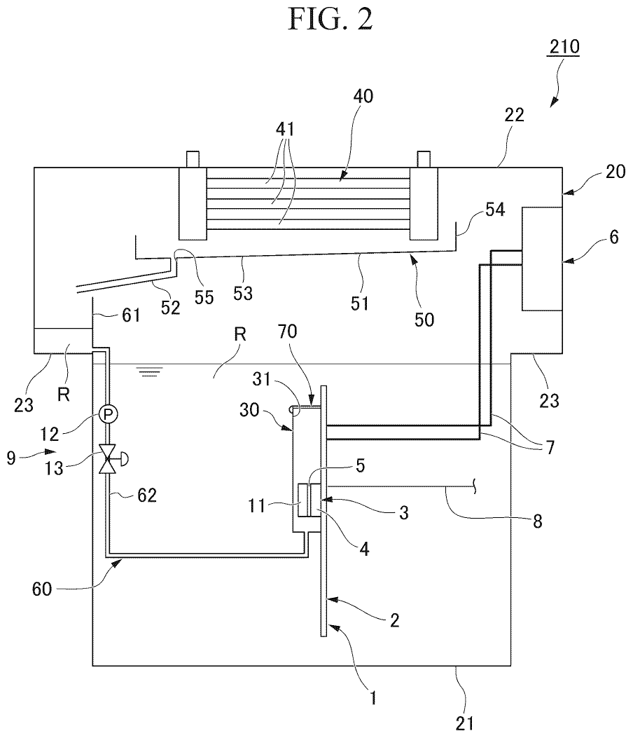

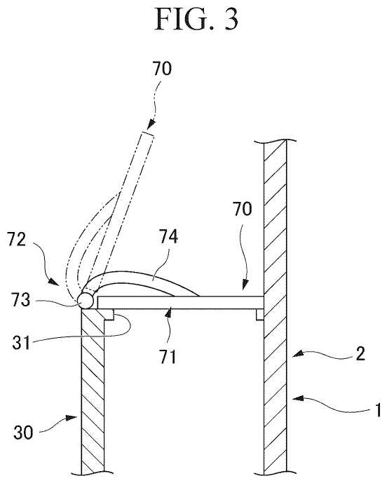

Hereinafter, a liquid immersion cooling device 210 according to a second embodiment of the present disclosure will be described with reference to FIGS. 2 and 3. For the same configuration as the configuration of the first embodiment, the same names and the same reference numerals are used, and a description thereof will be appropriately omitted.

As shown in FIG. 2, the liquid immersion cooling device 210 includes a lid portion 70 and a flow rate adjustment portion 9. FIG. 2 shows a state in which the server 1 is stopped and the heating element 3 does not generate heat.

### (Lid Portion)

The lid portion 70 is provided at the opening portion 31 of the cover 30. The lid portion 70 opens and closes the opening portion 31. Hereinafter, in the drawings, a state in which the lid portion 70 closes the opening portion 31 is shown by a solid line, and a state in which the lid portion 70 opens the opening portion 31 is shown by a two-dash chain line. As shown in FIG. 3, the lid portion 70 includes a lid portion body 71 and a check valve structure 72.

### (Lid Portion Body)

The lid portion body 71 is formed in a plate shape larger than the opening portion 31. In a case where the pressure of the refrigerant R flowing from the inside of the cover 30 toward the opening portion 31 is less than a predetermined value, the lid portion body 71 covers the entire opening portion 31 of the cover 30.

### (Check Valve Structure)

The check valve structure 72 pushes up the lid portion body 71 by the pressure of the refrigerant R to open the opening portion 31 in a case where the pressure of the refrigerant R flowing out of the cover 30 to the outside is equal to or greater than the predetermined value. The check valve structure 72 according to the present embodiment is a swing type. The check valve structure 72 includes a hinge 73 and an arm 74. The hinge 73 is provided in the vicinity of the opening portion 31 of the cover 30. One end of the arm 74 is coupled to the hinge 73. The other end of the arm 74 is coupled to the lid portion body 71. In a case where the pressure of the refrigerant R flowing from the inside of the cover 30 toward the opening portion 31 is equal to or greater than the predetermined value, the lid portion body 71 is pushed up by the flow of the refrigerant R toward the outside of the cover 30, and thus the opening portion 31 of the cover 30 is open, The arm 74 rotates about the hinge 73 due to the upward flow generated by the heat generation of the heating element 3.

A rotation angle of the arm 74 is set to be equal to or less than 90 degrees about the hinge 73. Therefore, in a case where the pressure of the refrigerant R flowing from the inside of the cover 30 toward the opening portion 31 is less than the predetermined value, the arm 74 and the lid portion body 71 are rotated about the hinge 73 by the dead weight of the arm 74 and the lid portion body 71, and the lid portion body 71 closes the opening portion 31 of the cover 30 again.

The check valve structure 72 may be provided with a spring that generates an elastic force in a direction in which the lid portion body 71 is pressed against the opening portion 31 of the cover 30.

### (Flow Rate Adjustment Portion)

The flow rate adjustment portion 9 includes a circulation pump 12 that pumps the refrigerant R of the refrigerant introduction flow channel 60 into the cover 30. The flow rate adjustment portion 9 adjusts the flow rate by the circulation pump 12 to temporarily store the refrigerant R on the upstream side in the refrigerant introduction flow channel 60. In the present embodiment, as an example, a case will be described in which the flow rate adjustment portion 9 includes a circulation pump 12 and a flow rate adjustment valve 13.

### (Circulation Pump)

The circulation pump 12 is provided in the refrigerant supply pipe 62 of the refrigerant introduction flow channel 60. The circulation pump 12 pumps the refrigerant R in the storage tank 61 into the cover 30.

### (Flow Rate Adjustment Valve)

The flow rate adjustment valve 13 is provided in the refrigerant supply pipe 62 of the refrigerant introduction flow channel 60. The flow rate adjustment valve 13 is provided on the cover 30 side with respect to the circulation pump 12. That is, the flow rate adjustment valve 13 is provided on the downstream side in the refrigerant supply pipe 62 in the flow direction of the refrigerant R with respect to the circulation pump 12. The flow rate adjustment valve 13 opens and closes the refrigerant supply pipe 62.

Further, the flow rate adjustment valve 13 adjusts the opening degree of the refrigerant supply pipe 62 to adjust the flow rate of the refrigerant R in the refrigerant supply pipe 62.

### (Operations and Effects)

With the liquid immersion cooling device 210 according to the present embodiment, the following operations and effects are exhibited.

In the present embodiment, the liquid immersion cooling device 210 further includes the flow rate adjustment portion 9 including the circulation pump 12 that pumps the refrigerant R in the refrigerant introduction flow channel 60 into the cover 30, and adjusts the flow rate via the circulation pump 12 and temporarily stores the refrigerant R on the upstream side in the refrigerant introduction flow channel 60.

As a result, the liquid immersion cooling device 210 can temporarily store the clean refrigerant R on the upstream side in the refrigerant introduction flow channel 60, adjust the flow rate of the clean refrigerant R supplied to the heating element 3 by the circulation pump 12 via the flow rate adjustment portion 9, and adjust the amount of the clean refrigerant R supplied to the heating element 3 and the timing of supplying the clean refrigerant R to the heating element 3. In the present embodiment, the flow rate adjustment portion 9 includes the circulation pump 12 and the flow rate adjustment valve 13, and the circulation pump 12 is provided in the refrigerant supply pipe 62 and pumps the refrigerant R in the storage tank 61 into the cover 30. The flow rate adjustment valve 13 adjusts the flow rate of the refrigerant R in the refrigerant supply pipe 62. The clean refrigerant R is temporarily stored in the storage tank 61, and the amount of the clean refrigerant R supplied to the heating element 3 and the timing of supplying the clean refrigerant R to the heating element 3 can be adjusted by the circulation pump 12 and the flow rate adjustment valve 13. Therefore, for example, before the operation of the server 1 is stopped, the liquid immersion cooling device 210 can reduce the supply amount of the refrigerant R supplied into the cover 30 and store the clean refrigerant R in the storage tank 61. Accordingly, the liquid immersion cooling device 210 can supply the refrigerant R to the heating element 3 by supplying the refrigerant R in the storage tank 61 to the inside of the cover 30 after the operation of the server 1 is stopped. Therefore, the precipitation and the accumulation of the impurities such as the oil component in the heating element 3 and the heat sink 11 are suppressed. Therefore, the decrease in the cooling efficiency of the liquid immersion cooling device 210 is suppressed.

In the present embodiment, the liquid immersion cooling device 210 includes the lid portion 70 that opens and closes the opening portion 31.

Accordingly, for example, when the heating element 3 does not generate heat, such as when the operation of the server 1 is stopped, the liquid immersion cooling device 210 can close the opening portion 31 of the cover 30 and store the clean refrigerant R in the cover 30. Therefore, even when the heating element 3 does not generate heat, the liquid immersion cooling device 210 can fill the inside of the cover 30 with the clean refrigerant R. Therefore, the precipitation and the accumulation of the impurities such as the oil component in the heating element 3 and the heat sink 11 are suppressed. Therefore, the decrease in the cooling efficiency of the liquid immersion cooling device 210 is suppressed.

In the present embodiment, the lid portion 70 has the check valve structure 72 that opens the opening portion 31 in a case where the pressure of the refrigerant R flowing out of the cover 30 is equal to or greater than the predetermined value.

Accordingly, the liquid immersion cooling device 210 can suppress flowing-back of the refrigerant R into the cover 30 by the check valve structure 72. Therefore, the liquid immersion cooling device 210 can suppress the inflow of the contaminated refrigerant R having a large amount of impurities stored in the casing 20 into the cover 30. Therefore, the precipitation and the accumulation of the impurities such as the oil component in the heating element 3 and the heat sink 11 are suppressed. Therefore, the decrease in the cooling efficiency of the liquid immersion cooling device 210 is suppressed.

In the second embodiment, the check valve structure 72 of the lid portion 70 is a swing type, but the present disclosure is not limited to this. For example, the check valve structure 72 of the lid portion 70 may be of a lift type.

In the second embodiment, the flow rate adjustment portion 9 includes the circulation pump 12 and the flow rate adjustment valve 13, but the present disclosure is not limited to this. For example, the flow rate adjustment portion 9 may not have the flow rate adjustment valve 13 and may have a control device (not shown), and the flow rate of the refrigerant R by the circulation pump 12 may be adjusted by controlling the rotation speed of the circulation pump 12 via the control device.

In addition, for example, even in a case where the storage tank 61 and the discharge pipe 52 are not provided, and the refrigerant supply pipe 62 is connected to the discharge hole 55 of the receiving portion body 51, the flow rate adjustment portion 9 can be applied. In this case, the liquid immersion cooling device 210 supplies the refrigerant R temporarily stored in the receiving portion body 51 into the cover 30 while adjusting the flow rate and the timing via the flow rate adjustment portion 9.

### Third Embodiment

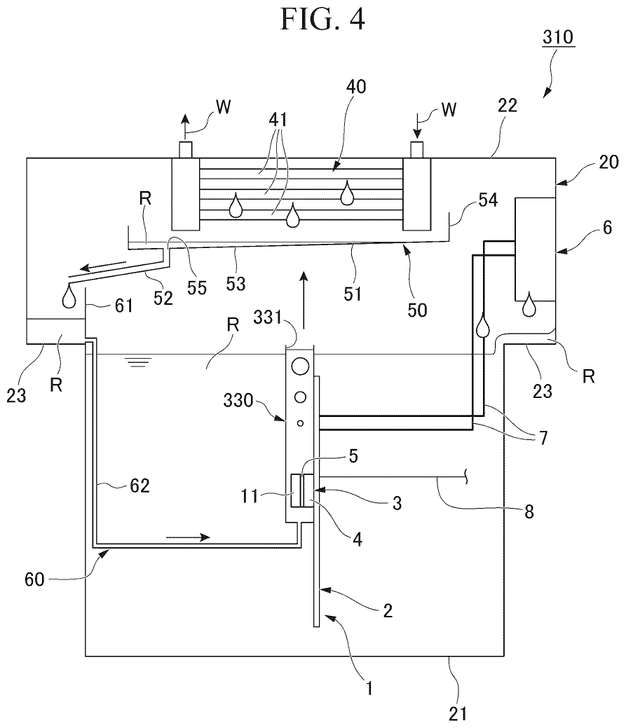

Hereinafter, a liquid immersion cooling device 310 according to a third embodiment of the present disclosure will be described with reference to FIG. 4. For the same configuration as the configuration of the first embodiment, the same names and the same reference numerals are used, and a description thereof will be appropriately omitted.

As shown in FIG. 4, the cover 330 protrudes above an upper edge of the board 2. FIG. 4 shows a state in which the server 1 is operated and the heating element 3 generates heat.

An opening portion 331 of the cover 330 is provided at a height equal to or higher than the liquid level of the refrigerant R stored in the casing 20. In the present embodiment, the opening portion 331 of the cover 330 is provided at a height equal to or higher than the connection wall 23 of the casing 20. The cover 330 and the board 2 are completely sealed with an epoxy resin or the like.

### (Operations and Effects)

With the liquid immersion cooling device 310 according to the present embodiment, the following operations and effects are exhibited.

In the present embodiment, the opening portion 331 is provided at a height equal to or higher than the liquid level of the refrigerant R stored in the casing 20.

As a result, the liquid immersion cooling device 310 can suppress the inflow of the refrigerant R containing the impurities stored in the casing 20 into the cover 330 through the opening portion 331. Therefore, the liquid immersion cooling device 310 can suppress the mixing of the clean refrigerant R in the cover 330 and the contaminated refrigerant R having a large amount of impurities in the casing 20. Therefore, the precipitation and the accumulation of the impurities such as the oil component in the heating element 3 and the heat sink 11 are suppressed. Therefore, the decrease in the cooling efficiency of the liquid immersion cooling device 310 is suppressed.

### Fourth Embodiment

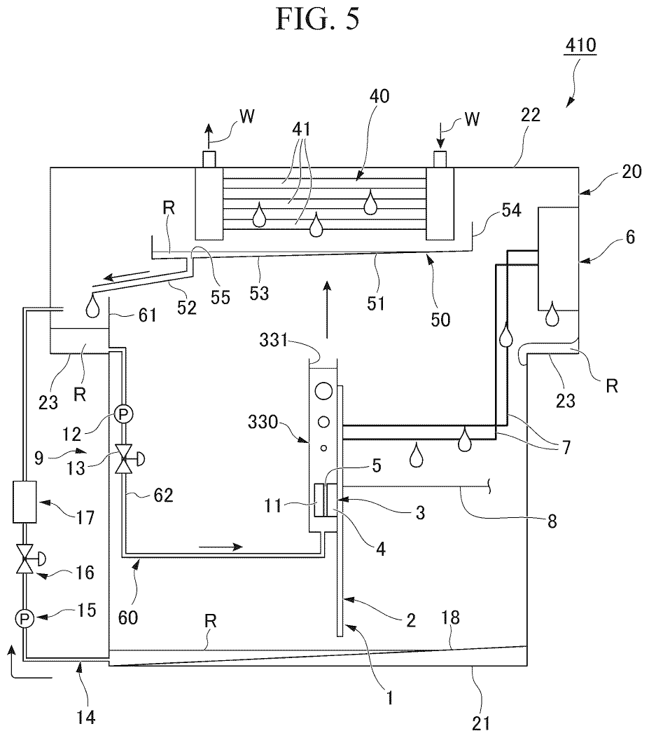

Hereinafter, a liquid immersion cooling device 410 according to a fourth embodiment of the present disclosure will be described with reference to FIG. 5. For the same configuration as the configurations of the first embodiment and other embodiments, the same names and the same reference numerals are used, and a description thereof will be appropriately omitted.

As shown in FIG. 5, as in the second embodiment, the flow rate adjustment portion 9 including the circulation pump 12 and the flow rate adjustment valve 13 is provided in the refrigerant supply pipe 62. In addition, as in the third embodiment, the opening portion 331 of the cover 330 is provided at a height equal to or higher than the liquid level of the refrigerant R stored in the casing 20. FIG. 5 shows a state in which the server 1 is operated and the heating element 3 generates heat.

The cover 330 and the board 2 are completely sealed with an epoxy resin or the like. The cover 330 is located above the liquid level of the refrigerant R stored in the casing 20.

In addition, the heat sink 11 is subjected to oil-repellent coating, The oil-repellent coating of the heat sink 11 is preferably fluorine-based coating. It should be noted that, in a case where the refrigerant R is a fluorine refrigerant, the material for the oil-repellent coating needs to have resistance to the fluorine refrigerant.

Further, the liquid immersion cooling device 410 includes an inclined plate 18, a refrigerant return flow channel 14, a return pump 15, a return amount adjustment valve 16, and a filter 17.

### (Inclined Plate)

The inclined plate 18 is provided at the inner lower portion of the casing 20. The inclined plate 18 extends in the horizontal direction. The inclined plate 18 is gradually inclined to be located downward toward the side wall of the casing 20 on the storage tank 61 side.

### (Refrigerant Return Flow Channel)

The refrigerant return flow channel 14 guides the refrigerant R stored in the casing 20 to the refrigerant introduction flow channel 60. The refrigerant return flow channel 14 is provided outside the casing 20. One end of the refrigerant return flow channel 14 is connected to a position corresponding to a lower end of the inclined plate 18 in the bottom portion of the casing 20. One end of the refrigerant return flow channel 14 is located slightly above the lower end of the inclined plate 18. The other end of the refrigerant return flow channel 14 is connected to an upper portion of the storage tank 61.

### (Return Pump)

The return pump 15 is provided in the refrigerant return flow channel 14. The return pump 15 pumps the refrigerant R in the casing 20 into the storage tank 61.

### (Return Amount Adjustment Valve)

The return amount adjustment valve 16 is provided in the refrigerant return flow channel 14. The return amount adjustment valve 16 is provided on the storage tank 61 side with respect to the return pump 15. That is, the return amount adjustment valve 16 is provided on the downstream side in the refrigerant return flow channel 14 in the flow direction of the refrigerant R with respect to the return pump 15. The return amount adjustment valve 16 opens and closes the refrigerant return flow channel 14. Further, the return amount adjustment valve 16 adjusts the opening degree of the refrigerant return flow channel 14, to adjust the flow rate of the refrigerant R in the refrigerant return flow channel 14.

### (Filter)

The filter 17 is provided in the refrigerant return flow channel 14. The filter 17 is provided on the storage tank 61 side with respect to the return amount adjustment valve 16. That is, the filter 17 is provided on the downstream side in the refrigerant return flow channel 14 with respect to the return amount adjustment valve 16 in the flow direction of the refrigerant R. The filter 17 collects the impurities in the refrigerant R. The filter 17 according to the present embodiment is, for example, an activated carbon filter.

(operations and Effects)

With the liquid immersion cooling device 410 according to the present embodiment, the following operations and effects are exhibited.

In the present embodiment, the liquid immersion cooling device 410 further includes the refrigerant return flow channel 14 and the filter 17. The refrigerant return flow channel 14 guides the refrigerant R stored in the casing 20 to the refrigerant introduction flow channel 60. The filter 17 is provided in the refrigerant return flow channel 14. The filter 17 collects the impurities in the refrigerant R.

Accordingly, the liquid immersion cooling device 410 can supply the refrigerant R to the heating element 3 after passing the refrigerant R stored in the casing 20 through the filter 17. The filter 17 removes the impurities of the refrigerant R stored in the casing 20. Therefore, the refrigerant R stored in the casing 20 becomes the clean refrigerant R before being supplied to the heating element 3. Therefore, the liquid immersion cooling device 410 can use the refrigerant R stored in the casing 20 for cooling the heating element 3. Therefore, the amount of the refrigerant R used is reduced as a whole of the liquid immersion cooling device 410.

In the present embodiment, the heat sink 11 is subjected to the oil-repellent coating. That is, the heat sink 11 has an oil-repellent coating layer on the surface.

According to the present embodiment, the cooling efficiency of the cooling device is improved by the heat sink 11. Further, the oil-repellent coating layer on the surface of the heat sink 11 suppresses the adhesion of the oil component to the heat sink 11. Therefore, the decrease in the cooling efficiency of the liquid immersion cooling device 410 is suppressed.

In the present embodiment, the cover 330 and the board 2 are completely sealed with an epoxy resin or the like.

As a result, the leakage of the clean refrigerant R in the cover 330 from the cover 330 is suppressed.

In the fourth embodiment, the filter 17 is the activated carbon filter, but the present disclosure is not limited to this.

### Fifth Embodiment

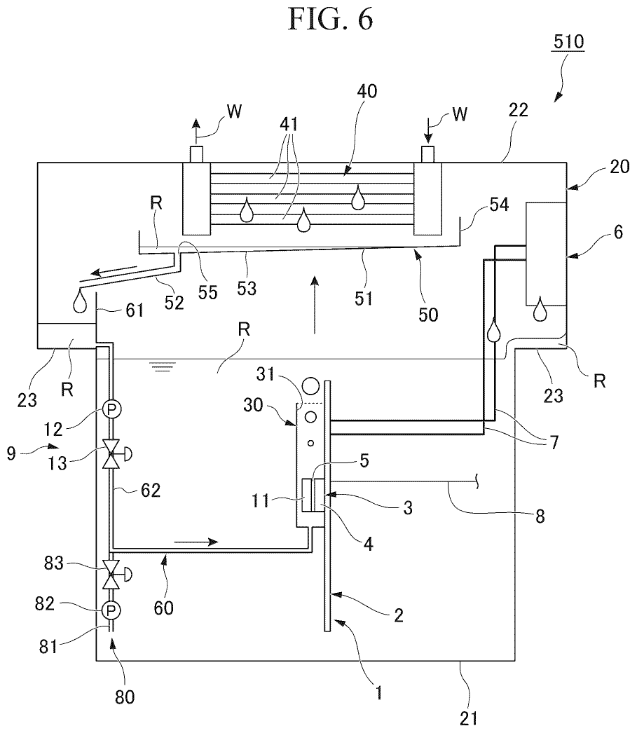

Hereinafter, a liquid immersion cooling device 510 according to a fifth embodiment of the present disclosure will be described with reference to FIG. 6. For the same configuration as the configurations of the first embodiment and other embodiments, the same names and the same reference numerals are used, and a description thereof will be appropriately omitted.

As shown in FIG. 6, as in the second embodiment, the flow rate adjustment portion 9 including the circulation pump 12 and the flow rate adjustment valve 13 is provided in the refrigerant supply pipe 62. In addition, as in the fourth embodiment, the heat sink 11 is subjected to the oil-repellent coating. FIG. 6 shows a state in which the server 1 is operated and the heating element 3 generates heat.

Further, the liquid immersion cooling device 510 includes a spray portion 80.

### (Spray Portion)

The spray portion 80 is a mechanism for spraying a fluid to the heating element 3. The spray portion 80 according to the present embodiment sprays the refrigerant R in the liquid phase in the casing 20 to the heating element 3. The spray portion 80 has a spray pipe 81 and a spray pump 82.

### (Spray Pipe)

The spray pipe 81 is provided in the casing 20. The spray pipe 81 is immersed in the refrigerant R in the casing 20. One end of the spray pipe 81 is open in the casing 20. The other end of the spray pipe 81 is connected to the refrigerant supply pipe 62. The spray pipe 81 communicates with the refrigerant supply pipe 62.

### (Spray Pump)

The spray pump 82 is provided in the spray pipe 81. The spray pump 82 pumps the refrigerant R in the casing 20 into the cover 30. Accordingly, a high-speed flow of the refrigerant R is supplied to the heating element 3 and the heat sink 11 in the casing 20.

### (Spray Amount Adjustment Valve)

A spray amount adjustment valve 83 is provided in the spray pipe 81. The spray amount adjustment valve 83 is provided on the refrigerant supply pipe 62 side with respect to the spray pump 82. That is, the spray amount adjustment valve 83 is provided on the downstream side in the spray pipe 81 in the flow direction of the refrigerant R with respect to the spray pump 82. The spray amount adjustment valve 83 opens and closes the spray pipe 81. Further, the spray amount adjustment valve 83 adjusts the opening degree of the spray pipe 81 to adjust the flow rate of the refrigerant R in the spray pipe 81.

### (Operations and Effects)

With the liquid immersion cooling device 510 according to the present embodiment, the following operations and effects are exhibited.

In the present embodiment, the liquid immersion cooling device 510 may includes the spray portion 80 that sprays the fluid to the heating element 3.

As a result, the liquid immersion cooling device 510 can spray the high-speed flow to the heating element 3 and the heat sink 11 by the spray portion 80. Therefore, even in a case where the impurities, such as the oil component, are attached to the heating element 3, the liquid immersion cooling device 510 can mechanically remove the impurities attached to the heating element 3 and the heat sink 11 by the high-speed flow supplied from the spray portion 80. Therefore, the decrease in the cooling efficiency of the liquid immersion cooling device 510 is suppressed. In addition, since the high-speed flow is supplied to the heating element 3 and the heat sink 11, the cooling efficiency of the liquid immersion cooling device 510 is further improved.

In the fifth embodiment, the spray pump 82 is separately provided in addition to the circulation pump 12 and the flow rate adjustment valve 13, but the present disclosure is not limited to this. For example, the circulation pump 12 and the flow rate adjustment valve 13 may be used as the spray portion 80. In this case, the high-speed flow of the clean refrigerant R in the storage tank 61 is sprayed to the heating element 3 and the heat sink 11.

In the fifth embodiment, a case has been described in which the spray portion 80 sprays the refrigerant R in the liquid phase to the heating element 3, but the present disclosure is not limited to this. The spray portion 80 may spray the refrigerant R in the gas phase to the heating element 3. In addition, the spray portion 80 may spray a fluid other than the refrigerant R to the heating element 3.

Although the embodiments of the present disclosure have been described in detail above with reference to the drawings, the specific configuration is not limited to this embodiment, and design changes and the like that do not depart from the gist of the present disclosure are also included.

In each of the above-described embodiments, the opening portions 31 and 331 are open upward, but the present disclosure is not limited to this. For example, the opening portions 31 and 331 may be provided on the side walls of the casing 20 and may be open in the horizontal direction.

In each of the above-described embodiments, the heat sink 11 is provided separately from the covers 30 and 330, but the present disclosure is not limited to this.

The heat sink 11 may have a structure integrated with the covers 30 and 330.

<supplementary Note>

The liquid immersion cooling devices 10, 210, 310, 410, and 510 described in each embodiment are understood, for example, as follows.

(1) A first aspect relates to a liquid immersion cooling device 10, 210, 310, 410, 510 that cools a heating element 3 provided on a board 2, the liquid immersion cooling device 10, 210, 310, 410, 510 including: a casing 20 configured to accommodate the board 2 inside and store a refrigerant R in an inner lower portion; a cover 30, 330 configured to surround at least the heating element 3 and having an opening portion 31, 331 at least in a part of the cover 30, 330; a condensation portion 40 provided above a liquid level of the refrigerant R in the casing 20 and configured to condense the refrigerant R that is evaporated; a refrigerant receiving portion 50 provided above the liquid level and below the condensation portion 40 and configured to receive the refrigerant R in a liquid phase condensed by the condensation portion 40; and a refrigerant introduction flow channel 60 configured to guide the refrigerant R received by the refrigerant receiving portion 50 into the cover 30, 330.

In the present aspect, the refrigerant R in the gas phase in the casing 20 is condensed by the condensation portion 40 and then changed to the liquid phase. The refrigerant R in the liquid phase is guided into the cover 30, 330 by the refrigerant receiving portion 50 and the refrigerant introduction flow channel 60. The refrigerant R condensed from the gas phase does not contain impurities such as a non-volatile oil component. Therefore, the refrigerant R supplied into the cover 30, 330 is the clean refrigerant R having few impurities.

In addition, the refrigerant R in the cover 30, 330 is heated by the heating element 3. As a result, the upward flow is generated in the cover 30, 330. The upward flow draws the clean refrigerant R in the refrigerant introduction flow channel 60 into the cover 30, 330. As a result, the clean refrigerant R is always supplied to the heating element 3 while the heating element 3 is generating heat.

(2) A second aspect relates to the liquid immersion cooling device 10, 210, 310, 410, 510 according to (1), in which the opening portion 31, 331 may be provided above the heating element 3.

As a result, the refrigerant R in the cover 30, 330 is likely to flow out of the cover 30, 330 through the opening portion 31, 331 due to the upward flow generated by the heating element 3.

(3) A third aspect relates to the liquid immersion cooling device 210, 410, 510 according to (1) or (2), which may further include: a flow rate adjustment portion 9 including a circulation pump 12 configured to pump the refrigerant R in the refrigerant introduction flow channel 60 into the cover 30, the flow rate adjustment portion 9 being configured to adjust a flow rate via the circulation pump 12 and temporarily store the refrigerant R on an upstream side in the refrigerant introduction flow channel 60.

As a result, the liquid immersion cooling device 210, 410, 510 can temporarily store the clean refrigerant R on the upstream side in the refrigerant introduction flow channel 60, adjust the flow rate of the clean refrigerant R supplied to the heating element 3 by the circulation pump 12 via the flow rate adjustment portion 9, and adjust the amount of the clean refrigerant R supplied to the heating element 3 and the timing of supplying the clean refrigerant R to the heating element 3.

(4) A fourth aspect relates to the liquid immersion cooling device 210 according to any one of (1) to (3), which may further include: a lid portion 70 configured to open and close the opening portion 31.

Accordingly, when the heating element 3 does not generate heat, the liquid immersion cooling device 210 can close the opening portion 31 of the cover 30 and store the clean refrigerant R in the cover 30.

(5) A fifth aspect relates to the liquid immersion cooling device 210 according to (4), in which the lid portion 70 may have a check valve structure 72 for opening the opening portion 31 in a case where a pressure of the refrigerant R flowing out of the cover 30 is equal to or greater than a predetermined value.

Accordingly, the liquid immersion cooling device 210 can suppress flowing-back of the refrigerant R into the cover 30 by the check valve structure 72.

(6) A sixth aspect relates to the liquid immersion cooling device 310, 410 according to any one of (1) to (5), in which the opening portion 331 may be provided at a height equal to or higher than the liquid level of the refrigerant R stored in the casing 20.

As a result, the liquid immersion cooling device 310, 410 can suppress the inflow of the refrigerant R containing the impurities stored in the casing 20 into the cover 30 through the opening portion 331.

(7) A seventh aspect relates to the liquid immersion cooling device 410 according to any one of (1) to (6), which may further include: a refrigerant return flow channel 14 configured to guide the refrigerant R stored in the casing 20 to the refrigerant introduction flow channel 60; and a filter 17 provided in the refrigerant return flow channel 14 and configured to collect impurities in the refrigerant R.

Accordingly, the liquid immersion cooling device 410 can supply the refrigerant R to the heating element 3 after passing the refrigerant R stored in the casing 20 through the filter 17. The filter 17 removes the impurities of the refrigerant R stored in the casing 20. Therefore, the refrigerant R stored in the casing 20 becomes the clean refrigerant R before being supplied to the heating element 3. Therefore, the liquid immersion cooling device 410 can use the refrigerant R stored in the casing 20 for cooling the heating element 3.

(8) An eighth aspect relates to the liquid immersion cooling device 410, 510 according to any one of (1) to (7), which may further include: a heat sink 11 disposed in the cover 30, 330 and thermally connected to the heating element 3, in which the heat sink 11 has an oil-repellent coating layer on a surface.

According to the present aspect, the cooling efficiency of the cooling device is improved by the heat sink 11. Further, the oil-repellent coating layer on the surface of the heat sink 11 suppresses the adhesion of the oil component to the heat sink 11.

(9) A ninth aspect relates to the liquid immersion cooling device 510 according to any one of (1) to (8), which may further include: a spray portion 80 configured to spray a fluid to the heating element 3.

Accordingly, the liquid immersion cooling device 510 can spray a high-speed flow to the heating element 3 by the spray portion 80. Therefore, even in a case where the impurities, such as the oil component, are attached to the heating element 3, the liquid immersion cooling device 510 can mechanically remove the impurities attached to the heating element 3 by the high-speed flow supplied from the spray portion 80.

### INDUSTRIAL APPLICABILITY

The present invention can be used for the liquid immersion cooling device that cools the heating element provided on a board.

### REFERENCE SIGNS LIST

1 Server

2 Board

3 Heating element

4 Heating element body

5 Cooling plate

6 Power supply

7 Power supply cable

8 Communication cable

9 Flow rate adjustment portion

10 Liquid immersion cooling device

11 Heat sink

12 Circulation pump

13 Flow rate adjustment valve

14 Refrigerant return flow channel

15 Return pump

16 Return amount adjustment valve

17 Filter

18 Inclined plate

20 Casing

21 Lower portion casing

22 Upper portion casing

23 Connection wall

30 Cover

31 Opening portion

40 Condensation portion

41 Heat transfer pipe

50 Refrigerant receiving portion

51 Receiving portion body

52 Discharge pipe

53 Bottom wall

54 Side wall

55 Discharge hole

60 Refrigerant introduction flow channel

61 Storage tank

62 Refrigerant supply pipe

70 Lid portion

71 Lid portion body

72 Check valve structure

73 Hinge

74 Arm

80 Spray portion

81 Spray pipe

82 Spray pump

83 Spray amount adjustment valve

210 Liquid immersion cooling device

310 Liquid immersion cooling device

330 Cover

331 Opening portion

410 Liquid immersion cooling device

510 Liquid immersion cooling device

R Refrigerant

W Cooling water

1. A liquid immersion cooling device that cools a heating element provided on a board, the liquid immersion cooling device comprising:
a casing configured to accommodate the board inside and store a refrigerant in an inner lower portion;
a cover configured to surround at least the heating element and having an opening portion at least in a part of the cover;
a condensation portion provided above a liquid level of the refrigerant in the casing and configured to condense the refrigerant that is evaporated;
a refrigerant receiving portion provided above the liquid level and below the condensation portion and configured to receive the refrigerant in a liquid phase condensed by the condensation portion; and
a refrigerant introduction flow channel configured to guide the refrigerant received by the refrigerant receiving portion into the cover.

2. The liquid immersion cooling device according to claim 1, wherein the opening portion is provided above the heating element.

3. The liquid immersion cooling device according to claim 1, further comprising:
a flow rate adjustment portion including a circulation pump configured to pump the refrigerant in the refrigerant introduction flow channel into the cover, the flow rate adjustment portion being configured to adjust a flow rate via the circulation pump and temporarily store the refrigerant on an upstream side in the refrigerant introduction flow channel.

4. The liquid immersion cooling device according to claim 1, further comprising:
a lid portion configured to open and close the opening portion.

5. The liquid immersion cooling device according to claim 4, wherein the lid portion has a check valve structure for opening the opening portion in a case where a pressure of the refrigerant flowing out of the cover is equal to or greater than a predetermined value.

6. The liquid immersion cooling device according to claim 1, wherein the opening portion is provided at a height equal to or higher than the liquid level of the refrigerant stored in the casing.

7. The liquid immersion cooling device according to claim 1, further comprising:
a refrigerant return flow channel configured to guide the refrigerant stored in the casing to the refrigerant introduction flow channel; and
a filter provided in the refrigerant return flow channel and configured to collect impurities in the refrigerant.

8. The liquid immersion cooling device according to claim 1, further comprising:
a heat sink disposed in the cover and thermally connected to the heating element, wherein the heat sink has an oil-repellent coating layer on a surface.

9. The liquid immersion cooling device according to claim 1, further comprising:
a spray portion configured to spray a fluid to the heating element.
